(19) United States
(12) Patent Application Publication
(10) Pub. No.: US 2011/0128701 A1
(43) Pub. Date: Jun. 2, 2011

(54) PROTECTIVE COVER FOR NOTEBOOK PERSONAL COMPUTER

(76) Inventor: Eagle Fan, Hsinchu (TW)

(21) Appl. No.: 12/627,189

(22) Filed: Nov. 30, 2009

(51) Int. Cl. H05K 5/03

(52) U.S. Cl. 361/679.55

(57) ABSTRACT

A protective cover for notebook PC is provided, including a set of bendable plates, and can be folded into a sideway U-shape. The protective cover is pressed tightly against the surface of a notebook PC, and can be opened in synch with the notebook PC screen. The bottom plate of the protective cover is for the placement of notebook PC. The bottom plate includes at least a support unit. The support unit is coupled to the bottom plate, located near the coupling side of the bottom plate. The support unit is divided at the coupling point on the bottom plate into at least an upper support element and a lower support element. When the support unit is opened up, the upper support element and the lower support element will protrude beyond the upper surface and the bottom surface of the bottom plate, so that when the notebook PC is placed on the bottom plate, a angle exists between the notebook PC and the bottom plate, and an angle exists between the bottom plate and the surface on which the protective cover is placed on. In this manner, the heat dissipation effect is improved when the notebook PC is in use.

### FIELD OF THE INVENTION

The present invention generally relates to a protective cover for notebook personal computer (PC), for protecting the notebook from scratch and providing better heat ventilation using notebook PC.

### BACKGROUND OF THE INVENTION

Notebook PC is widely used by many people. With the wireless network technology becoming readily available, more and more users, including business travelers, are using Internet as the major communication and information sources.

Heat ventilation is an issue when using notebook PC. When in use, the bottom of the notebook PC is preferably maintains good convection with outside so that the heat generated by the notebook PC can dissipated quickly to keep the PC running smoothly as well as prolong the lifespan of the PC. The notebook PC cover is a product to prevent the surface of the notebook PC from abrasion or scratching, and is usually placed on the upper and lower surfaces of the notebook PC. However, the design of having the cover placed against the surface of the bottom of the notebook PC will cause poor heat dissipation when the PC is in use. Therefore, it is advised to remove the cover from the notebook PC when using the PC, which is neither convenient nor practical as being prone to misplacing the removed cover. It is imperative to devise an innovative protective cover to solve the existing problem of the conventional protective cover.

### SUMMARY OF THE INVENTION

The primary object of the present invention is to provide a protective cover with heat dissipation effect for notebook PC. When the PC is not in use, the protective cover can protect the surface from abrasion; while when in use, the protective cover allows a heat dissipation space between the bottom of the notebook PC and the protective cover. In addition, the design can also include a tilting feature so that the keyboard of the notebook PC can exhibit a small angle tilt for convenience of use.

Another object of the present is to provide a protective cover with a heat-dissipation fan for notebook PC.

Yet another object of the present invention is to provide a protective cover with a speaker set for notebook PC.

To achieve the above objects, the present invention provides a protective cover for notebook PC, including a set of bendable plates, and can be folded into a sideway U-shape. The protective cover is pressed tightly against the surface of a notebook PC, and can be opened in synch with the notebook PC screen. The bottom plate of the protective cover is for the placement of notebook PC. The bottom plate includes at least a fastener element ad at least a support unit. The fastener element is located near to the profile side of the bottom plate. The profile side is the largest non-coupled side of the bottom plate to prevent the notebook PC from sliding towards the fastener element. The support unit is coupled to the bottom plate, located near the coupling side of the bottom plate. The support unit is divided at the coupling point on the bottom plate into at least an upper support element and a lower support element. When the support unit is opened up, the upper support element and the lower support element will protrude beyond the upper surface and the bottom surface of the bottom plate, so that when the notebook PC is placed on the bottom plate, a angle exists between the notebook PC and the bottom plate, and an angle exists between the bottom plate and the surface on which the protective cover is placed on. In this manner, the heat dissipation effect is improved when the notebook PC is in use.

Furthermore, the protective cover of the present invention includes a bottom plate, a side plate and a top plate. When the two opposite sides of the side plate are coupled to the bottom plate and the top plate respectively, the protective cover is folded into a side-way U-shape. In addition the top plate and the side plate can be flipped inside out along the coupling line so that the top plate is located beneath the bottom plate. After the support unit is opened, the upper support element and the lower support element cat still protrude beyond the top surface and the lower surface of the bottom plate. At this point, an angle exists between the bottom of the notebook PC and the bottom plate, and the lower support element pushes against the upper surface of the top plate so that an angle exists between the bottom plate and the top plate. In this manner, the notebook PC can be placed on a non-even surface for use, for example, the flat top plate can be placed on the lap of the user for using the notebook PC.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of the first embodiment according to the invention;

FIG. 2A shows a schematic view of the first embodiment when opened up, with two support units, for clear explanation, the left support unit is closed and the right support unit is opened;

FIG. 2B shows another schematic view of the first embodiment from a different angle when opened up; for clear explanation, the left support unit is closed and the right support unit is opened;

FIG. 3A shows an AA cross-sectional view of FIG. 2A;

FIG. 3B shows a BB cross-sectional view of FIG. 2A;

FIG. 4 shows a schematic view of the first embodiment in the first actual application;

FIG. 5 shows a schematic view of the first embodiment in the second actual application;

FIG. 6A shows a schematic view of the second embodiment of the present invention (1);

FIG. 6B shows a schematic view of the second embodiment of the present invention (2);

FIG. 7 shows a schematic view of the third embodiment of the present invention;

FIG. 8A shows a schematic view of the fourth embodiment of the present invention (1);

FIG. 8B shows a schematic view of the fourth embodiment of the present invention (2);

FIG. 9A shows a schematic view of the fifth embodiment of the present invention; and

FIG. 9B shows a schematic view of the fifth embodiment with the speakers moved side-way.

### DETAILED DESCRIPTION OF THE PREFERRED EMBODIMENTS

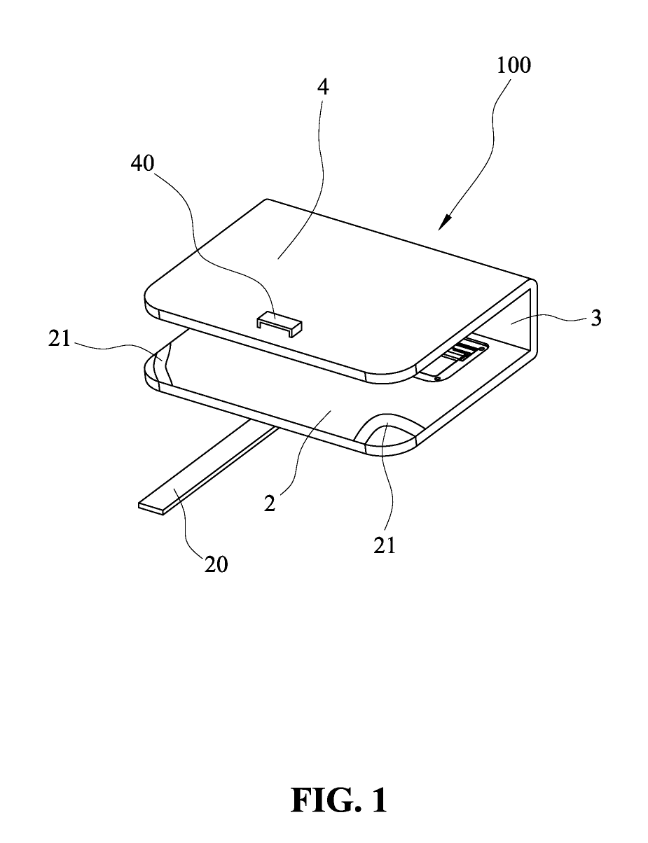

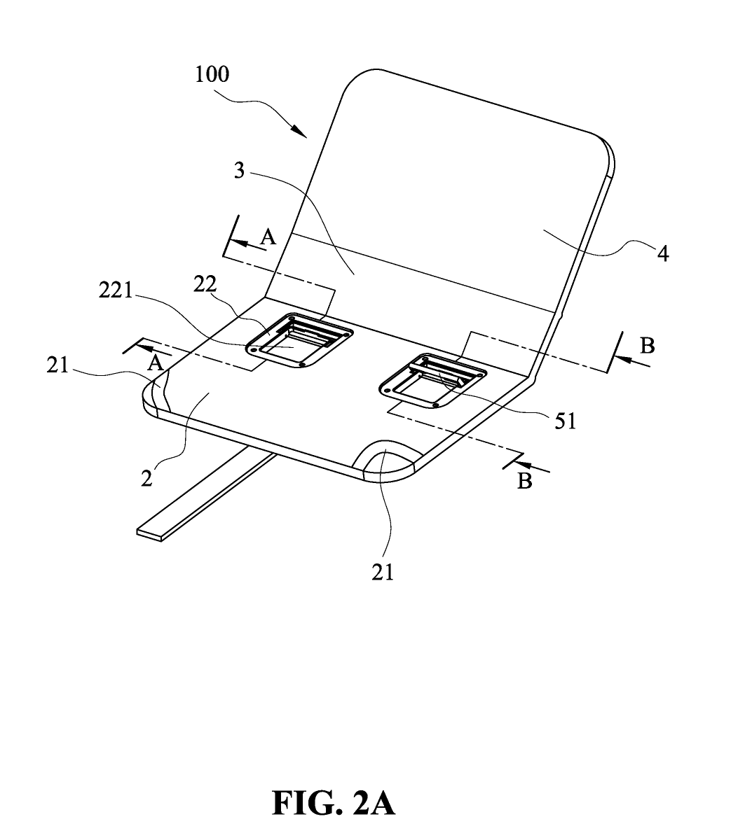

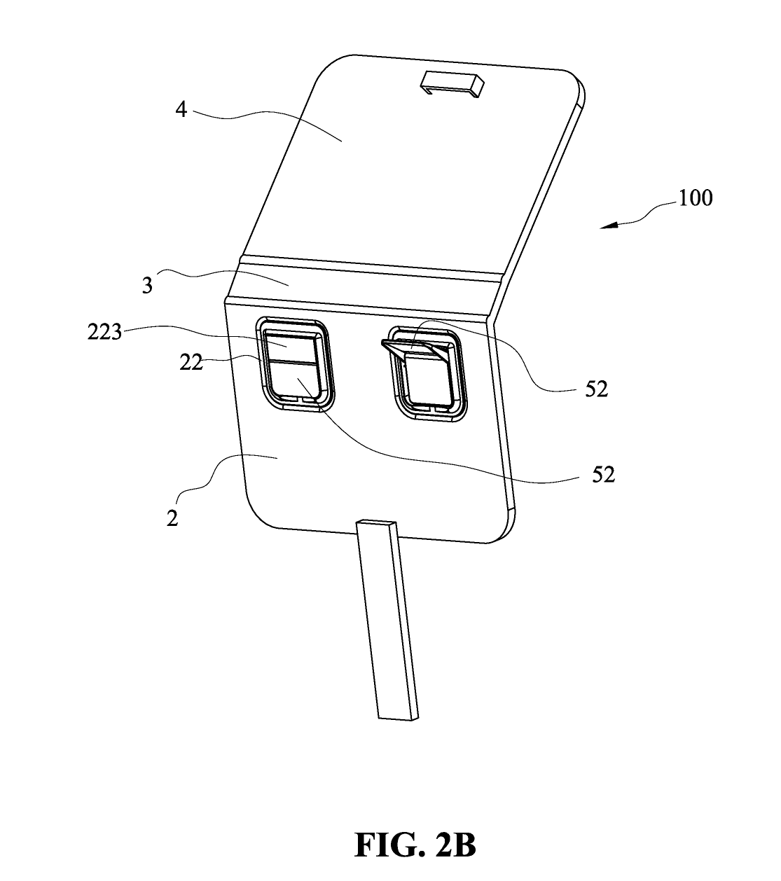

FIG. 1 shows a schematic view of a protective cover of the present invention. As shown in FIG. 1, protective cover 100 is a bendable set of plates that can be folded into a side-way U-shape for sheathing onto a notebook PC. As shown in FIG. 2A and FIG. 2B, protective cover 100 can be opened in synch with the opening of the screen of notebook PC. Bottom plate 2 of protective cover 100 is for placing notebook PC. The largest side of bottom plate 2 includes at least a fastener element 21. Protective cover 100 includes at least a support unit 5. Support unit 5 is coupled to bottom plate 2, preferably near the coupling side of bottom plate 2. In the present embodiment, the number of support units is 2, but is not limited to this specific number. Support unit 5 is divided at the coupling position into an upper support element 51 and a lower support element 52. When support unit 5 is opened, upper support element 51 and lower support element 52 protrude beyond the top surface and the bottom surface of bottom plate 2.

The following describes the structure of the present invention in details. As shown in FIG. 1, protective cover 100 includes a bottom plate 2, a side plate 3 and a top plate 4. The top and bottom opposite sides of side plate 3 are coupled to top plate 4 and bottom plate 2, respectively, to form a side-way U-shape. Bottom plate 2 at least includes a fastener element 21, located near the profile side of bottom plate 2. The profile side of bottom plate 2 is the largest non-coupling side of bottom plate 2. In this embodiment, two fastener elements 21 are included, having the shape of a belt, and located at the two corners of the profile side of bottom plate 2. When notebook PC is placed on bottom plate 2, fastener elements 21 are sheathed onto the two corners of the notebook PC to prevent the notebook PC from sliding towards to the fastener elements 21. The exposed surfaces of top plate 4 and bottom plate 2 have a buckle belt 20 and a buckle ring 40, respectively, for buckling up when the notebook PC is placed inside protective cover 100, wherein fastener elements 21, buckle belt 20 and buckle ring 40 are not limited to the structure shown in the present embodiment.

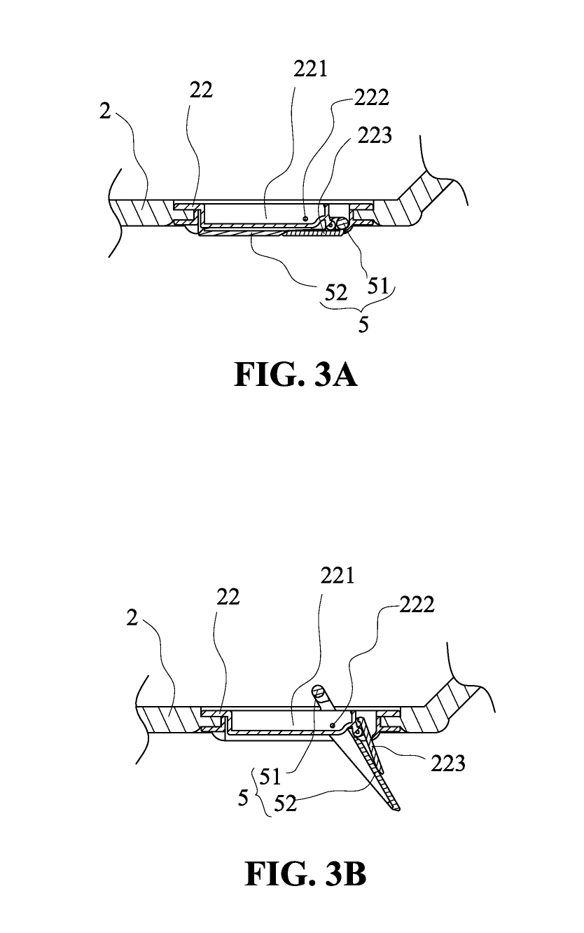

As shown in FIG. 2A and FIG. 2B, bottom plate 2 at least includes a frame set 22, for providing coupling to support unit 5. The present embodiment includes two frame sets 22, and forms a housing space 221 in the central area for housing small items, such as, USB connection. As shown in FIG. 3A and FIG. 3B, support unit 5 of the present invention is coupled to frame set 22, with coupling axis marked as 222. Support unit 5 includes an upper support element 51 and a lower support element 52. Before support unit 5 is opened, as shown in FIG. 3A, upper support element 51 is hidden in the other space of frame set 22. When support unit 5 is opened, as shown in FIG. 3B, upper support element 51 protrudes beyond the top surface of bottom plate 2 and lower support element 52 protrudes beyond the bottom surface of bottom plate 2. In the present embodiment, because of the interference between the elements, support unit 5 cannot completely conceal the bottom surface of frame set 22. Hence, an additional concealing element 223 is coupled to frame set 22. Concealing element 223 is linked to be moved by support unit 5. When support unit 5 is opened, concealing element 223 is also pushed open. When support unit 5 is pushed back to close, concealing element 223 will also be pressed back.

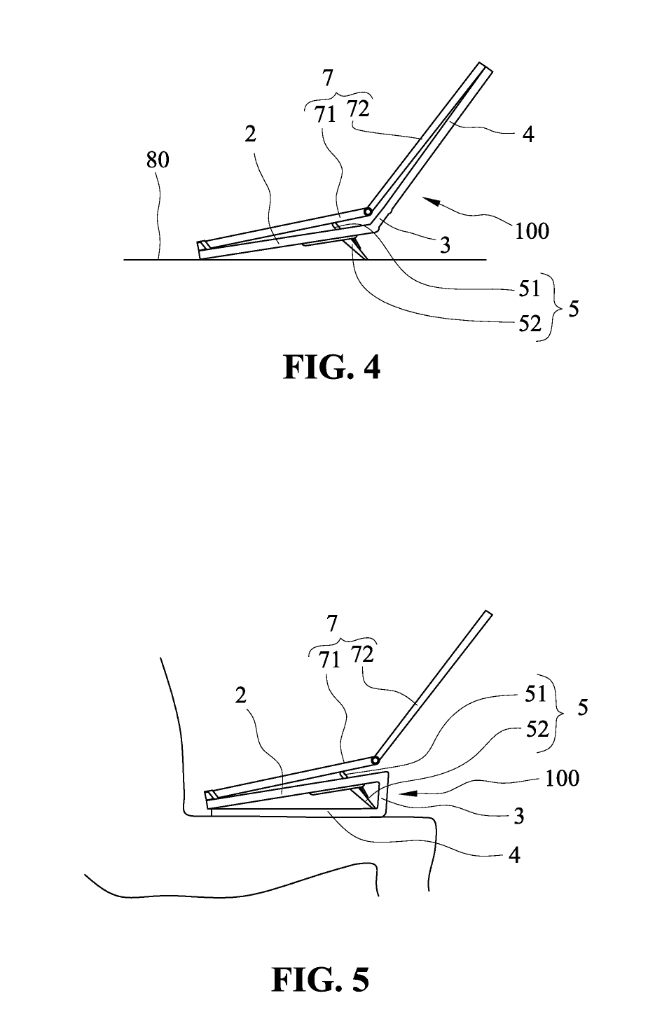

FIG. 4 shows a top view of the protective cover and notebook PC in actual application. As shown in FIG. 4, notebook PC 7 includes a host 71 and screen 72. When host 71 is placed on bottom plate 2 in use, support unit 5 is opened. Therefore, an angle exists between the bottom of host 71 and bottom plate 2, and another angle exists between the bottom surface of bottom plate 2 and surface 80 on which protective cover 100 is placed on so that a convection can easily take place between the cold air and heat generated by the notebook PC to improve the heat dissipation effect. In addition, because host 71 tilt a small angle, the operation on keyboard of host 71 is also easier and more convenient.

FIG. 5 shows a schematic view of another actual application of the present invention. Top plate 4 and side plate 3 of protective cover 100 can be complete flipped over so that top plate 4 is placed underneath bottom plate 2. At this point, support unit 5 is opened and upper support element 51 and lower support element 52 protrudes beyond the top surface and the bottom surface of bottom plate 2, respectively, so that an angle still exists between the notebook PC and bottom plate 2. Lower support element 52 pushes against the top surface of top plate 4 so that an angle also exists between bottom plate 2 and top plate 4. In this manner, the notebook PC can be placed on a non-even surface, while maintaining good heat dissipation effect. In this figure, the user is sitting and protective cover 100 and notebook PC 7 are placed on the lap of the user.

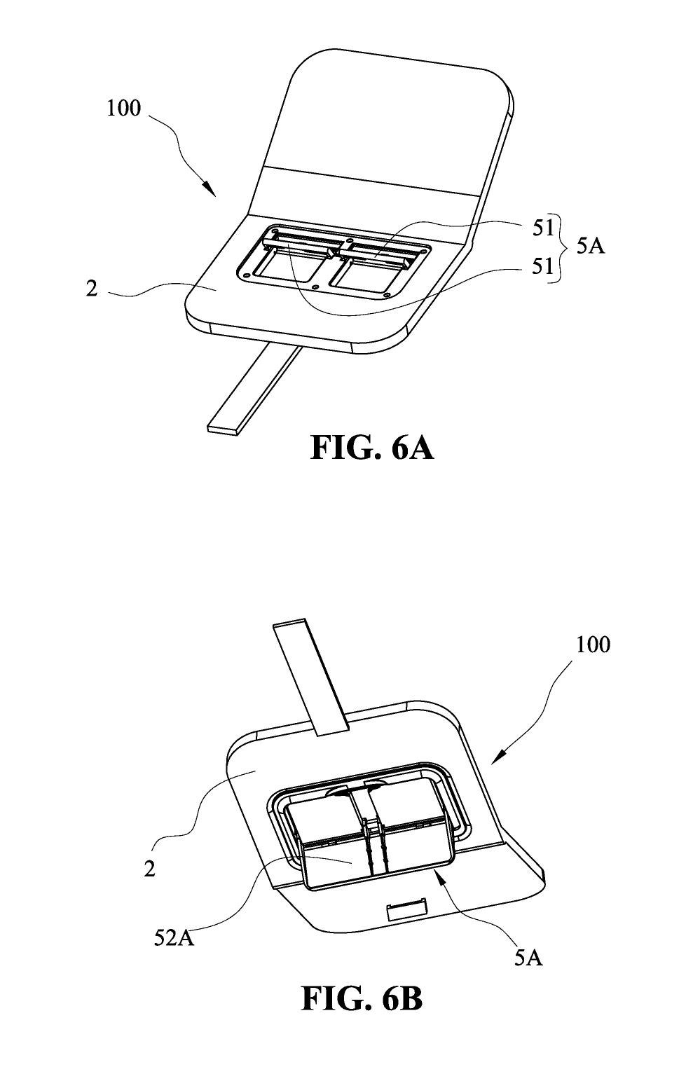

FIG. 6A and FIG. 6B show a schematic view of the second embodiment of the present invention. The main enhancement of this embodiment is the structure of support unit 5A. This embodiment only includes a support unit 5A, coupled to bottom plate 2 of protective cover 100. The use of support unit 5A is similar to the previous embodiment. Divided at the coupling position, the upper part of support unit 5A includes two upper support elements 51 and the lower part includes a large-area lower support element 52A. The present embodiment is more suitable for smaller size notebook PC.

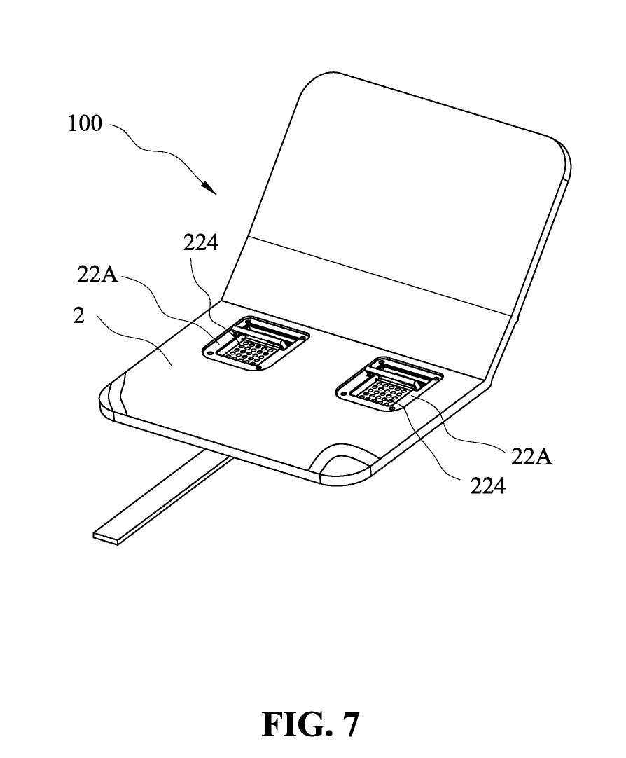

FIG. 7 shows a schematic view of the third embodiment of the present invention. The embodiment further includes an auxiliary heat dissipation structure. As shown in FIG. 7, frame set 22A includes a plurality of heat dissipation holes 224. When the notebook PC and protective cover 100 are in use, heat dissipation holes 224 allows the convection between the air above and below bottom plate 2 in order to expel the heat from notebook PC.

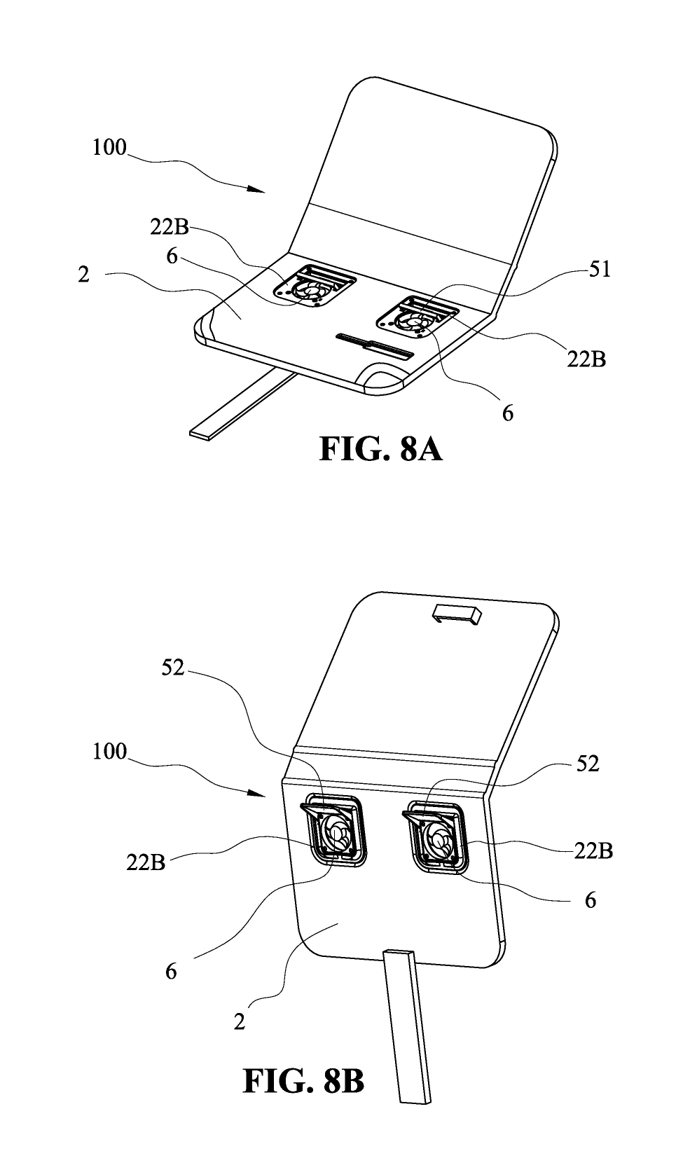

FIG. 8A and FIG. 8B show a schematic view of the fourth embodiment of the present invention. The main enhancement of this embodiment is the partial structure of frame set 22B. As shown in FIG. 8A and FIG. 8B, a fan set 6 is installed in frame set 22B of bottom plate 2. Fan set 6 uses a USB to connect to the notebook PC. The present embodiment uses fan set 6 to propel the heat dissipation. Frame set 22B, with fan set 6 installed, will not interfere the operation of support unit 5. Upper support element 51 and lower support element 52 still protrude beyond the top surface and the bottom surface of bottom plate 2.

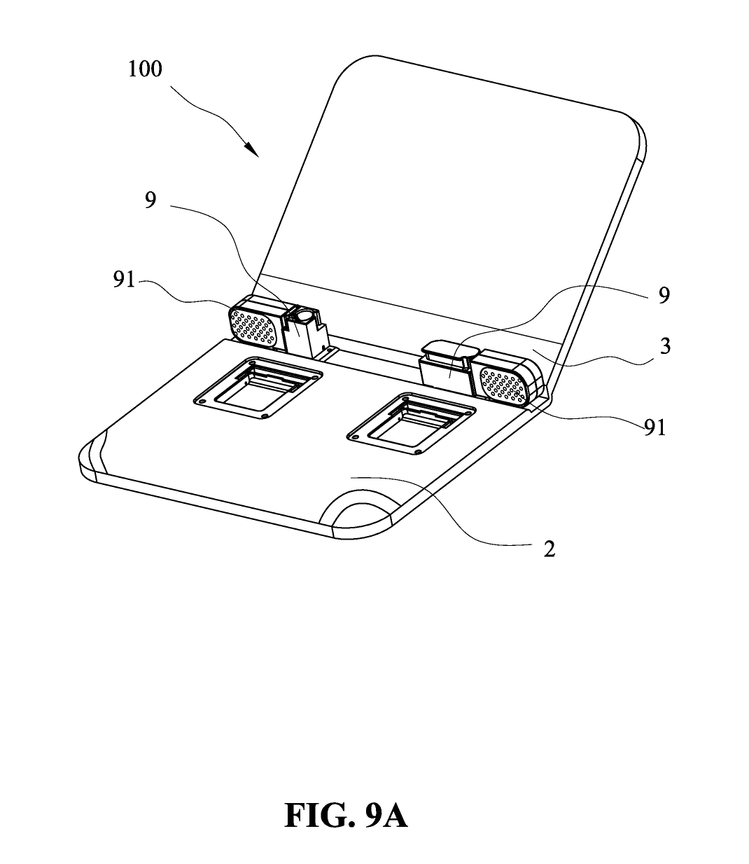

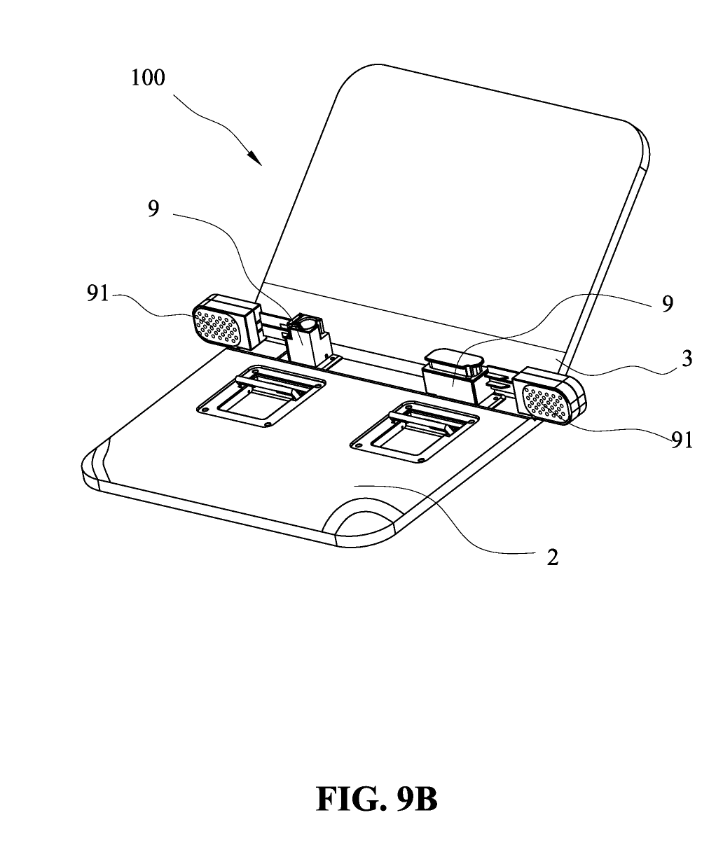

FIG. 9A shows a schematic view of the fifth embodiment of the present invention. The present embodiment is to install at least a speaker set 9 in protective cover 100. Two speaker sets are installed in this embodiment. Speaker set 9 is installed on bottom plate 2, located near the coupling position of bottom plate 2 and side plate 3. Two speaker sets are placed on opposite sides. As shown in FIG. 9B, speaker 91 of speaker set 9 can move collaterally and can move from inside to outside of protective cover 100. When in use, speaker 91 is located inside protective cover 100, and on both sides of the notebook PC facing the user for better acoustic effect.

In summary, the protective cover of the present invention can be sheathed onto the notebook PC to prevent from abrasion. When the notebook PC is in use, the bottom plate of the protective cover can use support unit to form an angle between the notebook PC and the bottom plate to improve heat dissipation and provide convenient use.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A protective cover for notebook PC, comprising a bendable set of plates, able to folded into a side-way U-shape; said protective cover being sheathed onto said notebook PC, and opened in synch with screen of said notebook PC; a bottom plate of said protective cover being for placing said notebook PC; said bottom plate having at least a fastener element and at least a support unit, said fastener element located near profile side of said bottom plate, said profile side being the largest non-coupling side of said bottom plate to prevent said notebook PC from sliding towards to said fastener element; said support unit being coupled to said bottom plate, located near coupling position of said bottom plate; said support unit divided at said coupling position into at least an upper support element and at least a lower support element; when said support unit opened up, said upper support element protruding beyond top surface of said bottom plate and said lower support element protruding beyond bottom surface of said bottom plate.

2. The protective cover as claimed in claim 1, wherein said protective cover comprises a bottom plate, a side plate and a top plate, wherein two opposite sides of said side plate are coupled to said bottom plate and said top plate respectively, said protective cover can be folded into a side-way U-shape.

3. The protective cover as claimed in claim 1, wherein the number of said support units is two.

4. The protective cover as claimed in claim 1, wherein said bottom plate comprises at least a frame set, said frame set can be coupled to said support unit.

5. The protective cover as claimed in claim 4, wherein said frame set further comprises a plurality of heat dissipation holes, said heat dissipation holes allow convection between he air above and below said bottom plate.

6. The protective cover as claimed in claim 3, wherein said frame set is installed with a fan set, said fan set propel to force the convection between the air above and below said bottom plate.

7. The protective cover as claimed in claim 1, wherein said protective cover is further installed with at least a speaker set.

8. The protective cover as claimed in claim 7, wherein said speaker set is installed on said bottom plate, located near coupling position of said side plate and said bottom plate.

9. The protective plate as claimed in claim 7, wherein two sets of speakers are installed, located on opposite sides of said bottom plate, moveable collaterally, when in use, said speakers can be moved from inside to outside of said protective cover.

10. The protective cover as claimed in claim 2, wherein said top plate and said side plate can be flipped over so that said top plate is located beneath said bottom plate, at this point, said support unit is opened, said upper support element and said lower support element still protrudes beyond top surface and bottom surface of said bottom plate respectively so that an angle exists between said notebook PC and said bottom plate, and an angle exists between said top plate and said bottom plate.
